(19) United States
(12) Patent Application Publication
(10) Pub. No.: US 2009/0008649 A1
(43) Pub. Date: Jan. 8, 2009

(54) Silicon carbide semiconductor device and method of manufacturing the same

(75) Inventor: Naohiro Suzuki, Anjo-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 12/155,012

(22) Filed: May 29, 2008

(30) Foreign Application Priority Data
Jul. 5, 2007 (JP) 2007-177282

(51) Int. Cl. H01L 29/24; H01L 21/04

(52) U.S. Cl. 257/77; 438/285; 257/E29.104; 257/E21.066

(57) ABSTRACT

A silicon carbide semiconductor device includes a substrate having one of a first conductivity type and a second conductivity type, a drift layer having the first conductivity type, a plurality of base regions having the second conductivity type, a plurality of source regions having the first conductivity type, a surface channel layer having the first conductivity type, a plurality of body layers having the second conductivity type, a gate insulation layer, a gate electrode, a first electrode, a second electrode, and a plurality of second conductivity-type regions. The first electrode is electrically coupled with the source regions and the body layers. The second conductivity-type regions are disposed at portions of the drift layer located under the body layers so as to be connected with the base regions respectively.

### CROSS REFERENCE TO RELATED APPLICATION

The present application is based on and claims priority to Japanese Patent Application No. 2007-177282 filed on Jul. 5, 2007, the contents of which are incorporated in their entirety herein by reference.

### BACKGROUND OF THE INVENTION

1. Field of the Invention

The present invention relates to a silicon carbide semiconductor device and a method of manufacturing the semiconductor device.

2. Description of the Related Art

U.S. Pat. No. 6,573,534 (corresponding to JP-11-266017A) discloses a vertical power metal-oxide semiconductor field-effect transistor (vertical power MOSFET) as an SiC semiconductor device used for a switching device. In the vertical power MOSFET, when voltage is not applied to a gate electrode, an n type channel-epitaxial layer (i.e., surface channel layer), which is located under the gate electrode and is disposed between a gate insulation layer and a p type base region, is fully-depleted by a depletion layer extending from the gate insulation layer and the p type base region. Thus, the MOSFET is tuned off. When voltage is applied to the gate electrode, a storage channel is provided in the n type surface channel layer located under the gate electrode. Thereby, a drain current flows between an n type drift layer and an n+ type source region.

When a load having an L-component, for example, a motor is driven by the vertical power MOSFET, a switching surge may become an issue. The switching surge is a surge generated at a time where the motor is switched between on and off by the vertical power MOSFET. The switching surge has a possibility to fracture the vertical MOSFET Specifically, when the motor is driven, the motor has an inductance L. Thus, when an electric current I flows in the motor, energy of LI³ is generated. The energy is applied to the vertical MOSFET when the vertical MOSFET turns off the motor, and thereby the MOSFET may be thermally fractured.

### SUMMARY OF THE INVENTION

In view of the foregoing problems, it is an object of the present invention to provide a silicon carbide semiconductor device that is difficult to be thermally fractured, and another aspect of the invention is to provide a method of manufacturing a silicon carbide semiconductor device.

According to a first aspect of the invention, a silicon carbide semiconductor device includes a substrate, a drift layer, a plurality of base regions, a plurality of source regions, a surface channel layer, a plurality of body layers, a gate insulation layer, a gate electrode, a first electrode, a second electrode, and a plurality of second conductivity-type regions. The substrate is made of silicon carbide and has one of a first conductivity type and a second conductivity type. The drift layer is disposed on a first surface of the substrate. The drift layer is made of silicon carbide having the first conductivity type and has an impurity concentration lower than an impurity concentration of the substrate. The base regions are disposed in the drift layer to have a predetermined distance therebetween and are made of silicon carbide having the second conductivity type. The source regions are disposed in the base regions respectively so as to be separated from the drift layer. The source regions are made of silicon carbide having the first conductivity type and have an impurity concentration higher than the impurity concentration of the drift layer. The surface channel layer is disposed on surfaces of portions of the base regions located between the source regions and the drift layer. The surface channel layer is made of silicon carbide having the first conductivity type. The body layers are disposed in the base regions respectively in such a manner that the source regions are located between the body layers and the surface channel layer. The gate insulation layer is disposed on a surface of the surface channel layer. The gate electrode is disposed on a surface of the gate insulation layer. The first electrode is electrically coupled with the source regions and the body layers. The second electrode is disposed on a second surface of the substrate. The second conductivity-type regions are disposed at portions of the drift layer located under the body layers so as to be connected with the base regions respectively. In the present silicon carbide semiconductor device, the surface channel layer provides a channel region and electric current flows between the first electrode and the second electrode through the source regions and the drift layer, when a voltage is applied to the gate electrode.

In the present silicon carbide semiconductor device, a thermal fracture due to a concentration of the drain current into the surface channel layer can be restricted.

According to another aspect of the invention, a method of manufacturing a silicon carbide semiconductor device, includes: preparing a substrate that is made of silicon carbide and that has one of a first conductivity type and a second conductivity type; forming a drift layer on a first surface of the substrate, wherein the drift layer has the first conductivity type and has an impurity concentration lower than an impurity concentration of the substrate; disposing a first mask on a surface of the drift layer, in which the first mask has a plurality of opening portion having a predetermined distance therebetween; implanting an impurity having the second conductivity type with the first mask using a first energy so as to form a plurality of base regions; disposing a second mask on the surface of the drift layer and a surface of the plurality of base region, in which the second mask has a plurality of opening portion that is located on a middle portion of the plurality of base regions respectively; implanting an impurity having the second conductivity type with the second mask using a second energy so as to form a plurality of second conductivity-type regions in the drift layer, in which the second energy is larger than the first energy and the plurality of second conductivity-type regions is connected with the plurality base regions respectively; forming a surface channel layer on the surface of the drift layer and the surface of the plurality of base regions; disposing a third mask on the surface channel layer, in which the third mask has a plurality of opening portions that is located over the plurality of the second conductivity-type regions respectively; implanting an impurity having the second conductivity type with the third mask so as to form a plurality of body layers; disposing a fourth mask on the surface channel layer, in which the fourth mask has a plurality of opening portions that is located on a portion of the surface channel layer located between the plurality body layers; implanting an impurity having the first conductivity type with the fourth mask to form a plurality of source regions; forming a gate insulation layer on a surface of the surface channel layer; forming a gate electrode on a surface of the gate insulation layer; forming a first electrode so as to be electrically coupled with the plurality of source regions and the plurality of body layers; and forming a second electrode on a second surface of the substrate.

The present method can manufacture a silicon carbide semiconductor device in which a thermal fracture due to a concentration of the drain current into the surface channel layer can be restricted.

### BRIEF DESCRIPTION OF THE DRAWINGS

Additional objects and advantages of the present invention will be more readily apparent from the following detailed description of preferred embodiments when taken together with the accompanying drawings. In the drawings:

FIG. 1 is a cross-sectional view illustrating a planer MOSFET included in an SiC semiconductor device according to a first embodiment of the invention;

FIG. 2A to FIG. 2D are cross-sectional views illustrating a manufacturing process of the planar MOSFET illustrated in FIG. 1;

FIG. 3A to FIG. 3D are cross-sectional views illustrating a manufacturing process of the planar MOSFET following to the manufacturing process illustrated in FIG. 2A to FIG. 2D;

FIG. 4 is a cross-sectional view illustrating passages of a surge current at a time where a switching surge is generated;

FIG. 5 is a timing diagram illustrating an input waveform of a gate voltage;

FIG. 6A and FIG. 6B are diagrams illustrating a distribution of an electric current density at time T1 where the planar MOSFET is turned off and at time T2 where the switching surge is generated, respectively.

FIG. 7 is a cross-sectional view illustrating a planer MOSFET included in an SiC semiconductor device according to a second embodiment of the invention;

FIG. 8A and FIG. 8B are cross-sectional views illustrating a manufacturing process of the planar MOSFET illustrated in FIG. 7;

FIG. 9 is a cross-sectional view illustrating a planer MOSFET included in an SiC semiconductor device according to a third embodiment of the invention;

FIG. 10 is a schematic diagram illustrating a circuit model for measuring a switching surge withstand;

FIG. 11 is a timing diagram illustrating a gate voltage, a drain current, and a drain voltage at a time where a switch is turned off by using the circuit model illustrated in FIG. 10; and

FIG. 12 is a schematic diagram illustrating a flow of an electric current in a vertical power MOSFET at a time where a switching surge is generated.

### DETAILED DESCRIPTION OF THE PREFERRED EMBODIMENTS

A mechanism of a thermal fracture of a vertical MOSFET will be described with reference to FIGS. 10-12 before describing preferred embodiments of the invention.

In a circuit model illustrated in FIG. 10, an inductance 30 as a substitute for a motor is arranged on a high side of a vertical MOSFET 31. In addition, a power source 32 (e.g., 650V) is coupled with the inductance 30, and a gate voltage having a pulse shape is applied to a gate of the inductance 30 through an input resistance 33.

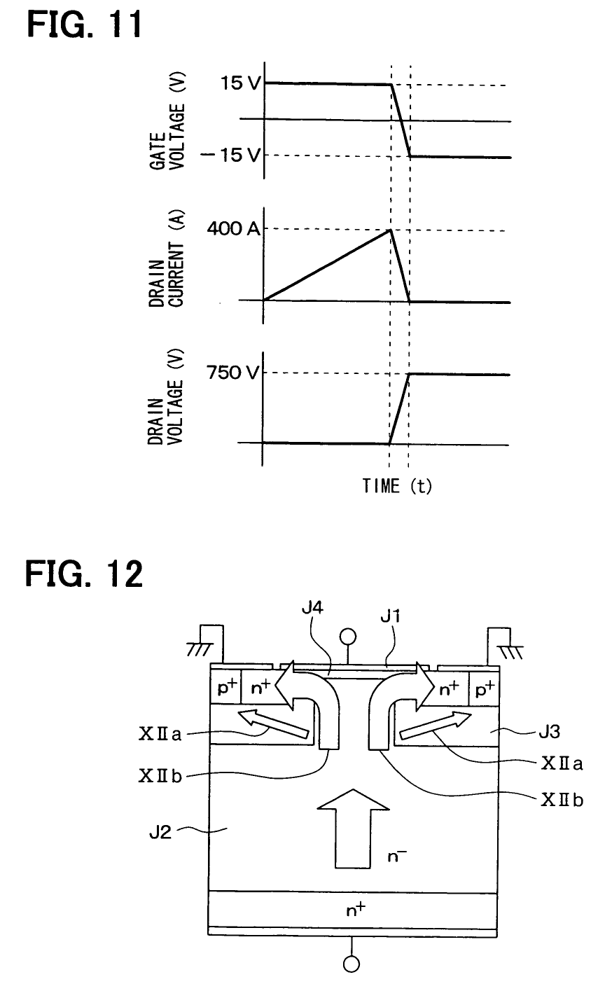

As illustrated in FIG. 11, when a switch is turned from on to off, that is, when the gate voltage is turned off, a drain current decreases and approaches zero, and a drain voltage increases, for example, to about 750 V. During the switch is turned from on to off, both the drain current and the drain voltage are not off state. Thus, electricity is applied to the vertical power MOSFET, and thereby the vertical power MOSFET may be thermally fractured.

Specifically, as illustrated in FIG. 12, when the gate voltage applied to a gate electrode J1 is turned off, a breakdown voltage increases and a PN diode including an n type drift layer J2 and p type base regions J3 has a breakdown in the reverse direction. Thereby, electric current flows in the p type base regions J3 as shown by the arrows XIIa. Then, voltage of the p type base regions J3 increases due to a resistance component in the p type base regions J3. Thus, a depletion layer extending from the p type base regions 3 to a surface channel layer J4 is disappeared, and thereby the electric current concentrates at the surface channel layer J4 as illustrated by the arrows XIIb. As a result, the thermal fracture occurs at the surface channel layer J4. The present invention is created based on the above-described finding.

### First Embodiment

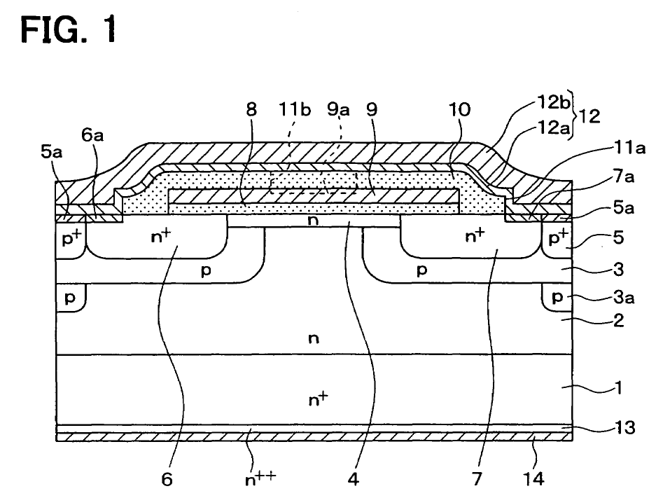

An SiC semiconductor device according to a first embodiment of the invention will be described with reference to FIGS. 1-6B. The SiC semiconductor device includes a planar MOSFET illustrated in FIG. 1, for example.

The planar MOSFET and a surrounding part are formed on a first surface of an n+ type substrate 1 made of SiC. The substrate 1 has a thickness about 300 μm. For example, the substrate 1 is a 4H-SiC substrate and the first surface is (11-20)-oriented surface. The substrate 1 has an impurity concentration about 1×10¹⁹ cm⁻³. As an n type impurity of the substrate 1, phosphorus may be used, for example.

On the first surface of the substrate 1, an n type drift layer 2 is formed of SiC by epitaxial growth. For example, the drift layer 2 has a thickness about 10 μm and has an impurity concentration about 5×10¹⁵ cm⁻³. Also as an n type impurity of the drift layer 2, phosphorous may be used.

At a surface portion of the n type drift layer 2, a plurality of p type base regions 3 is formed to have a predetermined distance therebetween. The base regions 3 are formed by ion implantation. For example, each of the base regions 3 has a thickness (a depth from a surface) in a range from about 0.4 μm to about 1.0 μm and has an impurity concentration in a range from about 1×10¹⁸ cm⁻³ to about 2×10¹⁹ cm⁻³. Although only a half of each of the base regions 3 is illustrated in FIG. 1, each of the base regions 3 is connected between adjacent cells. At an under portion of a middle portion of each of the base regions 3 connected between the adjacent cells, a p type layer 3a is formed. The p type layers 3a are provided for shifting a breakdown point of a PN diode, which is constructed from the p type base regions 3 and the n type drift layer 2, to positions under the base regions 3. Thus, an impurity concentration and a thickness of the p type layers 3a are unlimited. For example, the p type layers 3a have the impurity concentration in a range from about 1×10¹⁸ cm⁻³ to about 1×10²⁰ cm⁻³ and have the thickness in a range from about 0.4 μm to about 1.4 μm.

On the base regions 3, a surface channel layer 4 is formed. The surface channel layer 4 is made of an n type epitaxial layer. For example, the surface channel layer 4 has an impurity concentration about 1×10¹⁶ cm⁻³ and has a thickness (i.e., depth) about 0.3 μm.

At a position above each of the p type layers 3a, a p+ type body layer 5 is formed to penetrate through the surface channel layer 4 into the base region 3. For example, the body layers 5 have an impurity concentration about 1×10²¹ cm⁻³ and have a depth about 0.3 μm.

On an inside of the body layers 5, n+ type source regions 6 and 7 are formed to have a distance therebetween. The surface channel layer 4 is located between the source regions 6 and 7 and connects the drift layer 2 and the source regions 6 and 7. For example, the source regions 6 and 7 have an impurity concentration greater than or equal to about 3×10²⁰ cm⁻³ and have a depth in a range from about 0.3 μm to about 0.4 μm.

A part of the surface channel layer 4 that is located on the base regions 3 function as a channel region. A gate oxide layer 8 is formed to cover at least a surface of the channel region. For example, the gate oxide layer 8 has a thickness about 52 nm.

On the surface of the gate oxide layer 8, a gate electrode 9 is pattern-formed. For example, the gate electrode 9 is made of polysilicon in which an n type impurity (e.g., phosphorus) is doped.

In addition, an interlayer insulation layer 10 is formed to cover the gate electrode 9 and the rest of the gate oxide layer 8. For example, the interlayer insulation layer 10 is made of boron phosphorus silicate glass (BPSG). At the interlayer insulation layer 10 and the gate oxide layer 8, contact holes 11a extending to the body layers 5 and the source regions 6 and 7 and a contact hole 11b extending to the gate electrode 9 are provided.

In the contact holes 11a, contact parts 5a, 6a, 7a are disposed to be electrically coupled with the body layers 5, and the source regions 6 and 7, respectively. In the contact hole 11b, a contact part 9a is disposed to be electrically coupled with the gate electrode 9. Each of the contact parts 5a, 6a, 7a, and 9a is made of nickel or alloy of titan and nickel. Furthermore, a source electrode 12 and a gate wiring are formed. The source electrode 12 includes a base wiring electrode 12a made of titan and a wiring electrode 12b made of aluminum.

On a second surface of the substrate 1, an n++type drain contact region 13 is formed. The drain contact region 13 has an impurity concentration larger than the impurity concentration of the substrate 1.

On the drain contact region 13, a drain electrode 14 is formed. The drain electrode 14 is made of nickel, for example, and functions as a rear electrode.

In the above-described planar MOSFET included in the SiC semiconductor device, the surface channel layer 4 functions as the channel region, and electric current flows between the source regions 6 and 7 and the drain contact region 13 through the channel region. Electric current that flows between the source electrode 12 and the drain electrode 14 through the source regions 6 and 7 and the drain contact region 13 can be controlled by controlling voltage applied to the gate electrode 9, controlling a width of a depletion layer provided in the channel region, and controlling electric current flowing in the depletion layer.

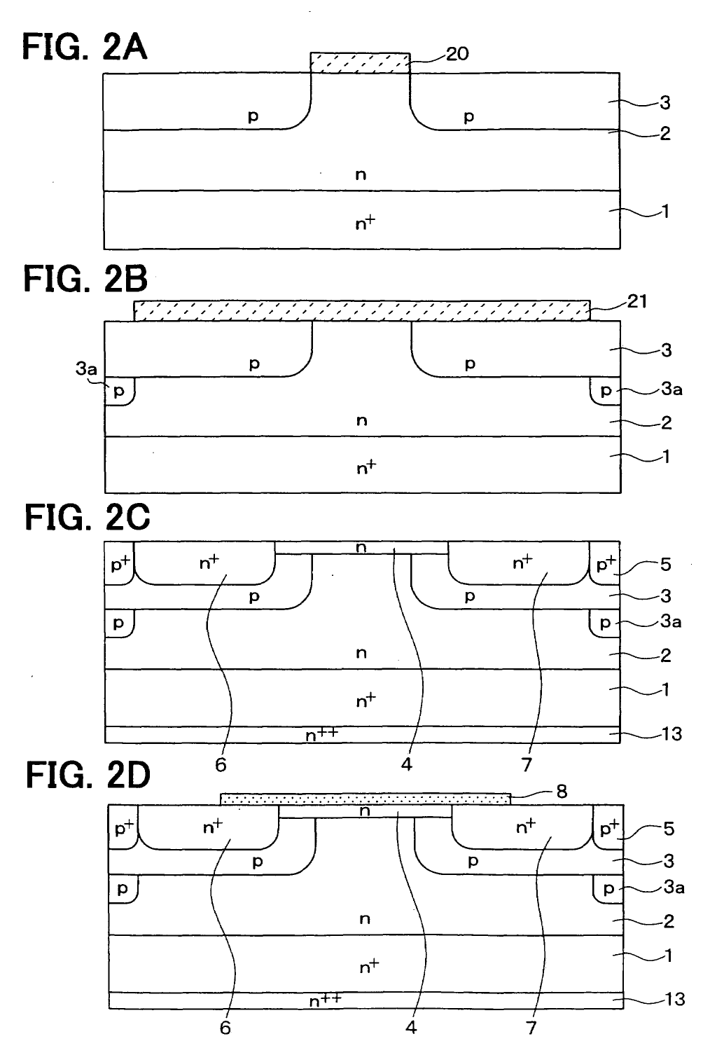

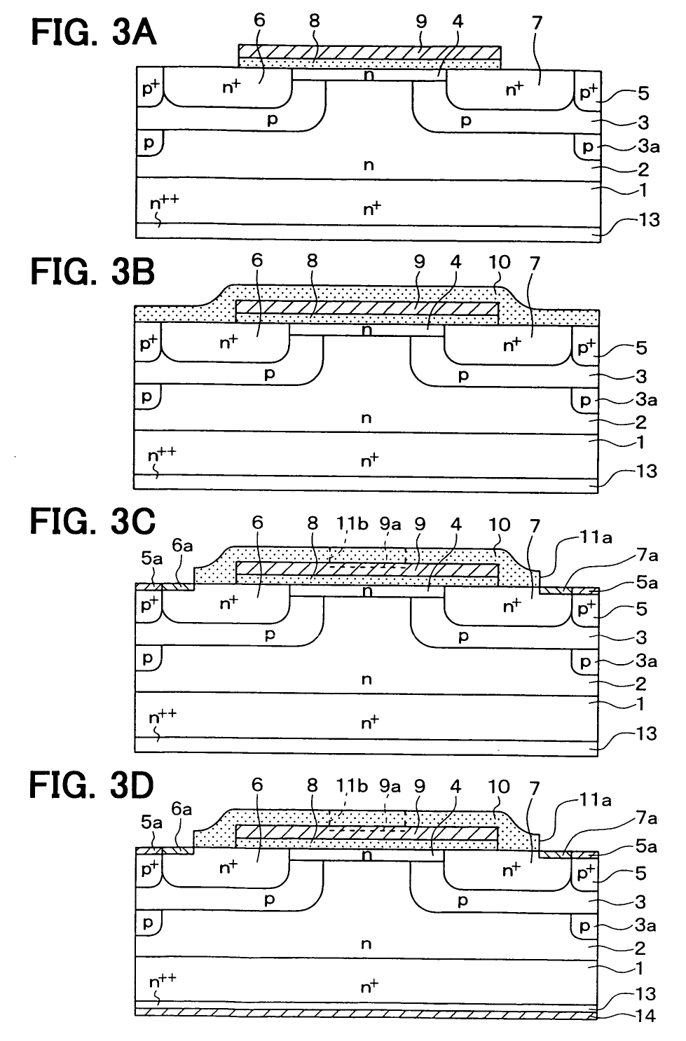

A manufacturing process of the SiC semiconductor device including the planar MOSFET will now be described with reference to FIGS. 2A-3D.

At first, the drift layer 2 is formed on the substrate 1 by epitaxial growth so as to have the impurity concentration about 5×10¹⁵ cm⁻³ and has the thickness about 10 μm.

On a surface of the drift layer 2, a mask 20 is disposed. The mask 20 is made of low temperature oxide (LTO) and has opening portions at positions where the base regions 3 are formed, as illustrated in FIG. 2A. Then, a p type impurity (e.g., aluminum) is ion-implanted from above the mask 20.

After removing the mask 20, a mask 21 made of LTO is disposed. The mask 21 has opening portions at positions where the p type layers 3a are formed, as illustrated in FIG. 2B. Then, a p type impurity (e.g., aluminum) is ion-implanted from above the mask 21. In the present time, energy of the ion implantation is higher than a case where the base regions 3 are formed. Thereby, ions are implanted to a position deeper than the base regions 3. After removing the mask 21, the substrate is treated with an activation anneal, for example, at about 1600° C. for about 30 minutes. Thereby, the ions that are implanted to the base regions 3 and the p type layers 3a are activated.

The ion implantation for forming the p type layers 3a may be performed by using a mask for forming the body layers 5 so as to simplify the manufacturing process. However, because SiC is hard, the ions are difficult to be implanted to a deep position. Thus, the ion implantation for forming the p type layers 3a may be performed before forming the surface channel layer 4.

On the base regions 3, the surface channel layer 4 is formed by epitaxial growth so as to have the impurity concentration about 1×10¹⁶ cm⁻³ and have the thickness about 0.3 μm. Then, a first mask, for example, made of LTO is formed on the surface channel layer 4. The first mask is treated by a photolithography process so that opening portions are provided at positions where the body layers 5 are formed. Then, a p type impurity (e.g., aluminum) is ion-implanted from above the first mask. After removing the first mask, a second mask made of LTO is formed on an upper surface of the substrate (i.e., surfaces of the surface channel layer 4 and the body layers 5) and an n type impurity (e.g., phosphorus) is ion-implanted from a side of the second surface of the substrate 1. After removing the second mask, a third mask made of LTO is formed. The third mask is treated with a photolithography process so that opening portions are provided at positions where the source regions 6 and 7 are formed. Then, an n type impurity (e.g., phosphorus) is ion-implanted. After removing the third mask, the substrate is treated with an activation anneal, for example, at about 1600° C. for about 30 minutes so that the implanted p type impurity and n type impurity are activated. Thereby, as illustrated in FIG. 2C, the body layers 5, the source regions 6 and 7, and the drain contact region 13 are formed.

Next, as illustrated in FIG. 2D, the gate oxide layer 8 is formed by a pyrogenic method with a wet atmosphere.

On the gate oxide layer 8, a polysilicon layer is formed, for example, at about 600° C., so as to have a thickness about 440 nm. In the polysilicon layer, an n type impurity is doped. Then, the polysilicon layer and the gate oxide layer 8 are patterned with a mask made of a resist that is formed by a photolithography etching. Thereby, the gate electrode 9 is formed as illustrated in FIG. 3A.

Next, the interlayer insulation layer 10 is formed on the whole upper surface of the substrate, as shown in FIG. 3B. For example, a BPSG layer is formed by a plasma chemical vapor deposition (plasma CVD) at about 420° C. so as to have a thickness about 670 nm. Then, the substrate is treated with a reflow process at about 930° C. for about 20 minutes with a wet atmosphere, and thereby the interlayer insulation layer 10 is formed.

Next, the interlayer insulation layer 10 is patterned with a mask made of a resist that is formed by a photolithography etching. Thereby, the contact holes 11a extending to the body layers 5 and the source regions 6 and 7 and the contact hole 11b extending to the gate electrode 9 are provided as illustrated in FIG. 3C. The contact hole 11b are provided at a cross-sectional surface other than a cross-sectional surface illustrated in FIG. 3C.

Then, a contact metal layer made of nickel or alloy of titan and nickel is formed to fill the contact holes 11a and 11b. The contact metal layer is patterned so that the contact parts 5a, 6a, 7a, and 9a are formed. The contact parts 5a, 6a, 7a, and 9a are electrically coupled with the body layers 5, the source regions 6 and 7, and the gate electrode 9, respectively.

Next, as illustrated in FIG. 3D, the drain electrode 14 is formed on the second surface of the substrate 1 so as to contact the drain contact region 13. Then, the substrate is heat-treated at 700° C. or less with argon atmosphere, and thereby each of the contact parts 5a, 6a, 7a, and 9a and the drain electrode 14 form an ohmic junction. In the present case, each of the body layers 5, the source regions 6 and 7, the gate electrode 9, and the drain contact region 13 has a high impurity concentration as described above. Thus, each of the contact parts 5a, 6a, 7a, and 9a and the drain electrode 14 can form the ohmic junction without a heat treatment at a high temperature over 700° C.

After the manufacturing process illustrated in FIG. 3D, the source electrode 12 including the base wiring electrode 12a and the wiring electrode 12b and the gate wiring (not shown) are formed. The gate wiring is formed at a cross-sectional surface other than a cross-sectional surface illustrated in FIG. 1. As a result, the planar MOSFET illustrated in FIG. 1 is formed.

In the present SiC semiconductor device including the planar MOSFET, each of the p type layers 3a is formed at the position under the middle portion of the p type base region 3, which is connected between the adjacent cells. More specifically, each of the p type layers 3a is formed at the position under the body layer 5 that is coupled with the source electrode 12.

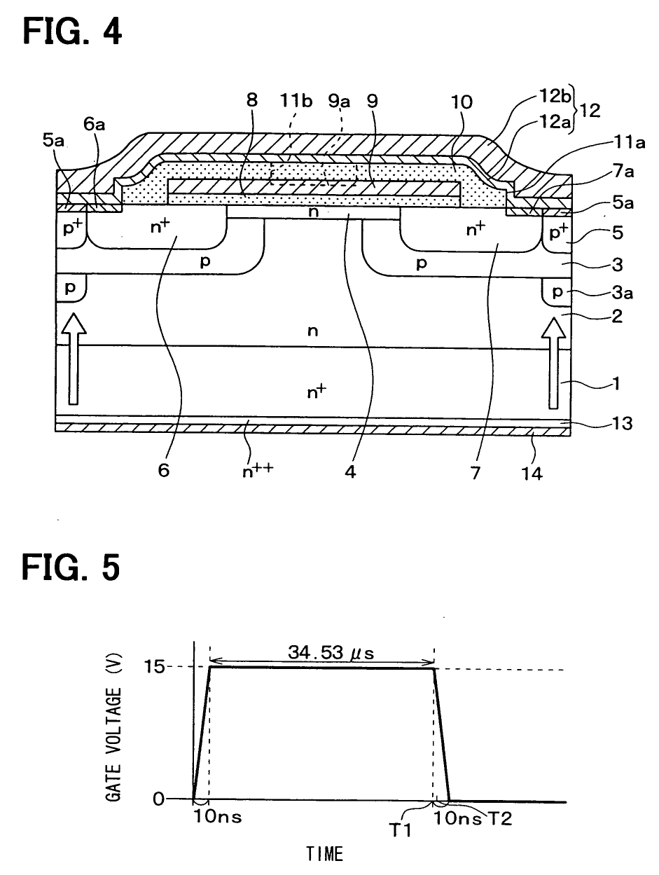

Thus, when the gate voltage applied to the gate electrode 9 is turned off and the breakdown voltage applied to the planar MOSFET increases, the breakdown point of the PN diode, which is constructed from the p type base regions 3 and the n type drift layer 2, is positioned at the p type layers 3a disposed at the positions under the p type base regions 3. Therefore, as illustrated by the arrows in FIG. 4, the surge current can flow in order of the drift layer 2, the p type layers 3a, the base regions 3, and the body layers 5. That is, when the switching surge is generated, the surge current is introduced to passages from the p type layers 3a toward the body layers 5, and thereby the surge current is restricted from flowing to the surface channel layer 4. As a result, a thermal fracture due to a concentration of the drain current into the surface channel layer 4 can be restricted.

The switching surge withstand can be measured by using the circuit model illustrated in FIG. 10 as was demonstrated by the inventor. Specifically, as illustrated in FIG. 5, a switching simulation can be performed in such a manner that the gate voltage is increased to 15 V for 10 ns, then the gate voltage is kept at 15V for 34.53 μs, and the gate voltage is decreased to 0 V for 10 ns. As a result, the PN diode, which is constructed from the n type drift layer 2 and the p type base regions 3, has a properties that the breakdown voltage is 1300 V, an on voltage is 3V, the drain current is 400 A, a reverse recovery time is 0.3 μs, and a forward current reduction rate is 1400 μA/μs. When an element area is 1.34 cm², a thermal resistance is 0.0074 K/W, that is, the thermal resistance is 0.0133 K·cm²/W.

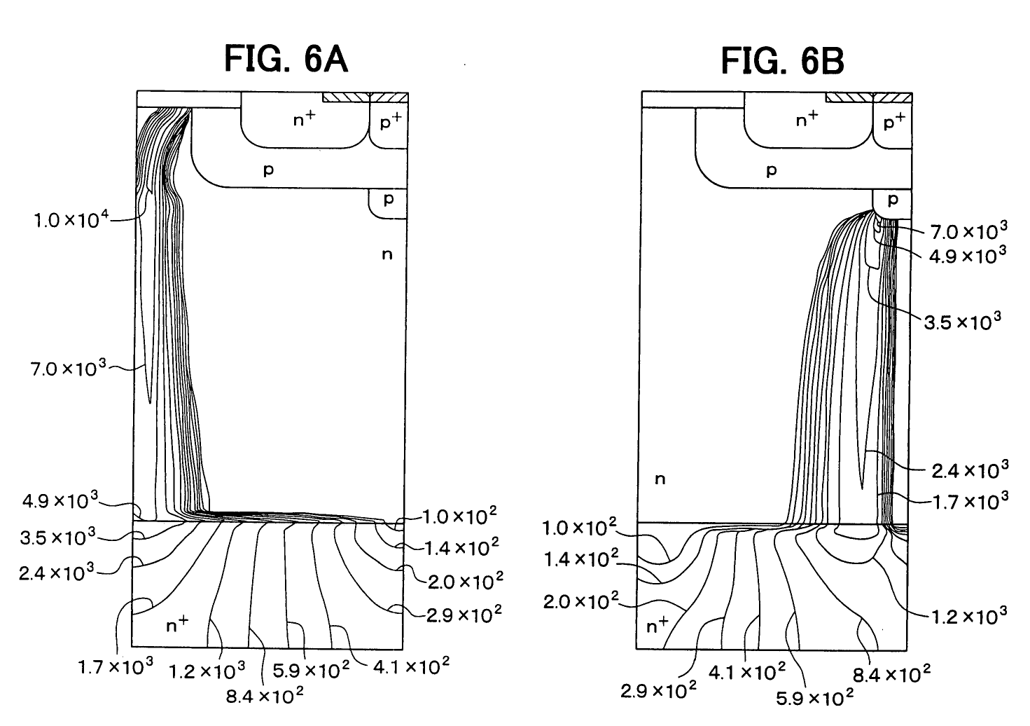

In addition, a distribution of electric current density (A/cm²) is examined at a time T1 where the planar MOSFET is turned off, specifically, after 34.64 μs since the gate voltage has been started to be increased, and at a time T2 where the switching surge is generated after the predetermined time has passed since the planar MOSFET is turned off, specifically, after 34.84 μs since the gate voltage has been started to be increased. As illustrated in FIG. 6A, the drain current flows through the surface channel layer 4 at time T1. However, as illustrated in FIG. 6B, the surge current flows through the p type layers 3a at time T2. As described above, in the present SiC semiconductor device including the planar MOSFET, the surge current at a time where the switch is turned off can flow in order of the drift layer 2, the p type layers 3a, the base regions 3, and the body layers 5. Thus, a thermal fracture due to a concentration of the drain current into the surface channel layer 4 can be restricted.

### Second Embodiment

In an SiC semiconductor device according to a second embodiment of the invention, the body layers 5 are different from those in the SiC semiconductor device according to the first embodiment. The other part of the present SiC semiconductor device is similar to that of the SiC semiconductor device according to the first embodiment.

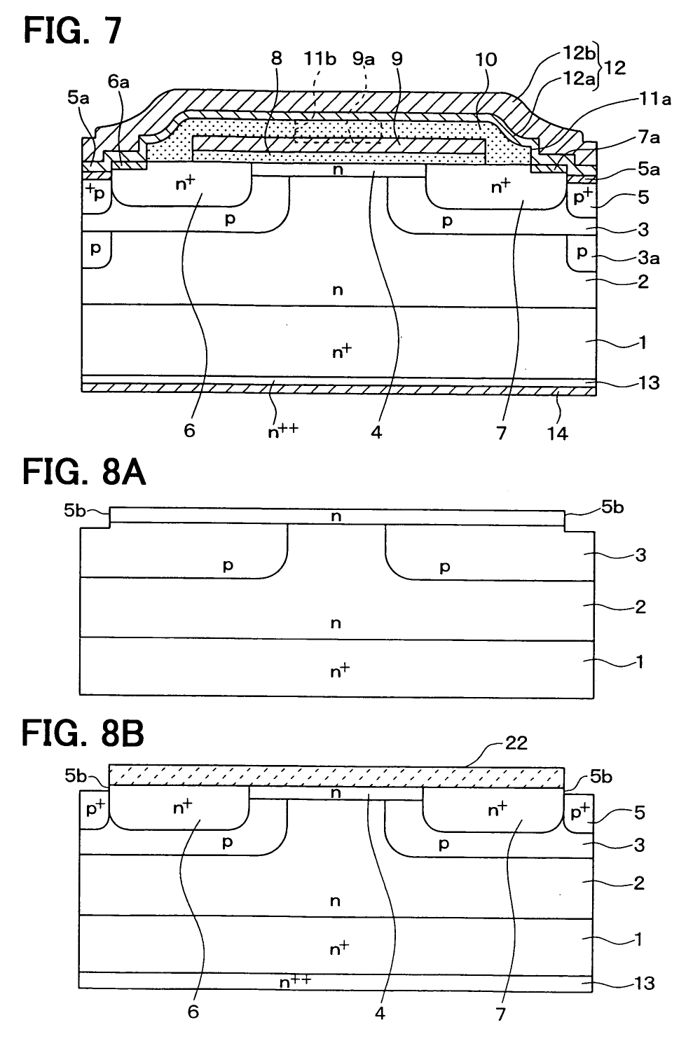

As illustrated in FIG. 7, the type body layers 5 of the present SiC semiconductor device have a thickness less than the thickness of the body layers of the SiC semiconductor device illustrated in FIG. 1 so that the passage of the surge current becomes short. Specifically, the thickness of the body layers 5 is reduced by providing hollow portions 5b at positions where the body layers 5 are formed.

In the present case, because the passage of the surge current becomes short, a resistance at the passage is reduced. Thereby, the surge current can be introduced more effectively. Thus, when the switching surge is generated, a thermal fracture due to a concentration of the drain current into the surface channel layer 4 can be restricted more effectively.

For manufacturing the present SiC semiconductor device, a process illustrated in FIG. 8A and FIG. 8B is performed instead of the process illustrated in FIG. 2C. The other part of the manufacturing process is similar to the manufacturing process illustrated in FIGS. 2A, 2B, 2D, and 3A-3D. As illustrated in FIG. 8A, after forming the surface channel layer 4, a mask 22 is disposed on the substrate. The mask 22 has opening portion at positions where the body layers 5 are formed. By using the mask 22, the hollow portions 5b extending to the base regions 3 are provided.

Then, as illustrated in FIG. 8B, the p type impurity is ion-implanted with the mask 22 so as to form the body layers 5, and the substrate is heat-treated for the activation. Because the mask 22 can be used for providing the hollow portions 5b and forming the body layers 5, the manufacturing process can be simplified.

After forming the body layers 5, the mask 22 is removed and the source regions 6 and 7 are formed. Furthermore, the process illustrated in FIGS. 2D-3D is performed for manufacturing the present SiC semiconductor device.

When the hollow portions 5b are provided, a distance from the surfaces (i.e., bottom surface) of the hollow portions 5b to the p type layers 3a becomes short. Thus, when the ions are implanted from the surfaces of the hollow portions 5b for forming the p type layers 3a, the energy of the ion implantation can be reduced compared with a case where the ions are implanted from the surface of the surface channel layer 4. Thus, the ion implantation for forming the p type layers 3a may be performed by using the mask 22. In the present case, the manufacturing process can be more simplified.

### Third Embodiment

In an SiC semiconductor device according to a third embodiment of the invention, the p type layers 3a are different from those in the SiC semiconductor device according to the first embodiment. The other part of the present SiC semiconductor device is similar to that of the SiC semiconductor device according to the first embodiment.

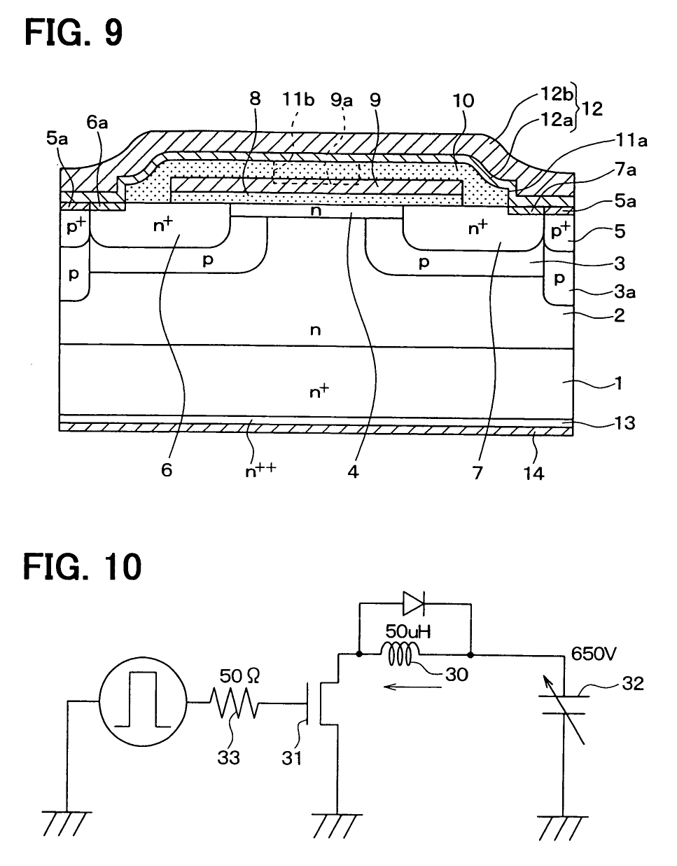

As illustrated in FIG. 9, in the present SiC semiconductor device, the p type layers 3a penetrate through lower portions of the base regions 3 to reach the body layers 5. In addition, the p type layers 3a have an impurity concentration about 1×10²⁰ cm⁻³, which is higher than the impurity concentration of the p type layers 3a of the SiC semiconductor device illustrated in FIG. 1.

Thereby, the resistance of the surge current in the passage is reduced, and the surge current can be introduced to the passage more effectively. Thus, when the switching surge is generated, a thermal fracture due to a concentration of the drain current into the surface channel layer 4 can be restricted.

The present SiC semiconductor device can be manufactured by changing a box profile at a time where the p type layers 3a are formed in the process illustrated in FIG. 2B.

### Other Embodiments

Although the present invention has been fully described in connection with the preferred embodiments thereof with reference to the accompanying drawings, it is to be noted that various changes and modifications will become apparent to those skilled in the art.

In the SiC semiconductor device according to the third embodiment, the body layers 5 are formed from positions at the same height as the surfaces of the source regions 6 and 7, as an example. Alternatively, the hollow portions 5b may be provided so that the bottom surfaces of the hollow portions 5b, which are lower than the surfaces of the source regions 6 and 7, become the surfaces of the body layers 5 in a manner similar to the SiC semiconductor device according to the second embodiment.

In the SiC semiconductor devices according to the first to third embodiments, the p type layers 3a are located only at the positions under the body layers 5. Alternatively, the p type layers 3a may extend to positions located under the source regions 6 and 7 for a predetermined distance.

The SiC semiconductor devices according to the first to third embodiments respectively include the n channel type MOSFET as an example. Alternatively, the SiC semiconductor devices may respectively include a p channel type MOSFET in which conductivity types of the components are reversed.

The SiC semiconductor devices according to the first to third embodiments respectively include the planar MOSFET, as an example. Alternatively, the SiC semiconductor devices may respectively include an insulated gate bipolar transistor (IGBT) in which a substrate has a p type conductivity.

Such changes and modifications are to be understood as being within the scope of the present invention as defined by the appended claims.

What is claimed is:

1. A silicon carbide semiconductor device comprising:
a substrate that is made of silicon carbide, that has one of a first conductivity type and a second conductivity type, and that has a first surface and a second surface;
a drift layer that is disposed on the first surface of the substrate, that is made of silicon carbide having the first conductivity type, and that has an impurity concentration lower than an impurity concentration of the substrate;
a plurality of base regions that is disposed in the drift layer to have a predetermined distance therebetween and that is made of silicon carbide having the second conductivity type;
a plurality of source regions that is disposed in the plurality of base regions respectively so as to be separated from the drift layer, that is made of silicon carbide having the first conductivity type, and that has an impurity concentration higher than the impurity concentration of the drift layer;
a surface channel layer that is disposed on a surface of a portion of the plurality of base regions located between the plurality of source regions and the drift layer, and that is made of silicon carbide having the first conductivity type;
a plurality of body layers that is disposed in the plurality of base regions respectively in such a manner that the plurality of source regions is located between the plurality of body layers and the surface channel layer;
a gate insulation layer that is disposed on a surface of the surface channel layer;
a gate electrode that is disposed on a surface of the gate insulation layer;
a first electrode that is electrically coupled with the plurality of source regions and the plurality of body layers;
a second electrode that is disposed on the second surface of the substrate; and
a plurality of second conductivity-type regions that is disposed at a portion of the drift layer located under the plurality of body layers so as to be connected with the plurality of base regions respectively, wherein:
the surface channel layer provides a channel region and an electric current flows between the first electrode and the second electrode through the plurality of source regions and the drift layer, when a voltage is applied to the gate electrode.

2. The silicon carbide semiconductor device according to claim 1, wherein
a surface of the plurality of body layers is hollow with respect a surface of the plurality of source regions.

3. The silicon carbide semiconductor device according to claim 1, wherein
the plurality of second conductivity-type regions extends to the plurality of body layers respectively.

4. The silicon carbide semiconductor device according to claim 1, wherein
the plurality of second conductivity-type regions is disposed only at the portion of the drift layer located under the plurality of body layers.

5. A method of manufacturing a silicon carbide semiconductor device, comprising:
preparing a substrate that is made of silicon carbide and that has one of a first conductivity type and a second conductivity type;
forming a drift layer on a first surface of the substrate, wherein the drift layer has the first conductivity type and has an impurity concentration lower than an impurity concentration of the substrate;
disposing a first mask on a surface of the drift layer, wherein the first mask has a plurality of opening portion having a predetermined distance therebetween;
implanting an impurity having the second conductivity type with the first mask using a first energy so as to form a plurality of base regions;
disposing a second mask on the surface of the drift layer and a surface of the plurality of base region, wherein the second mask has a plurality of opening portion that is located on a middle portion of the plurality of base regions respectively;
implanting an impurity having the second conductivity type with the second mask using a second energy so as to form a plurality of second conductivity-type regions in the drift layer, wherein the second energy is larger than the first energy and the plurality of second conductivity-type regions is connected with the plurality base regions respectively;
forming a surface channel layer on the surface of the drift layer and the surface of the plurality of base regions;
disposing a third mask on the surface channel layer, wherein the third mask has a plurality of opening portions that is located over the plurality of the second conductivity-type regions respectively;
implanting an impurity having the second conductivity type with the third mask so as to form a plurality of body layers;
disposing a fourth mask on the surface channel layer, wherein the fourth mask has a plurality of opening portions that is located on a portion of the surface channel layer located between the plurality body layers;
implanting an impurity having the first conductivity type with the fourth mask so as to form a plurality of source regions;
forming a gate insulation layer on a surface of the surface channel layer;
forming a gate electrode on a surface of the gate insulation layer;
forming a first electrode so as to be electrically coupled with the plurality of source regions and the plurality of body layers; and
forming a second electrode on a second surface of the substrate.

6. The method according to claim 5, further comprising
providing a plurality of hollow positions by using the third mask before implanting the impurity to form the plurality of body layers, wherein the plurality of hollow portion extends to the plurality of base regions respectively.
